(19) United States
(12) Patent Application Publication
(10) Pub. No.: US 2025/0241032 A1
(43) Pub. Date: Jul. 24, 2025

(54) DIODE AND SEMICONDUCTOR DEVICE

(71) Applicants: SAMSUNG ELECTRONICS CO., LTD., Suwon-si (KR); POSTECH RESEARCH AND BUSINESS DEVELOPMENT FOUNDATION, Pohang-si (KR)

(72) Inventors: Won Joon CHO, Suwon-si (KR); Gil-ho LEE, Pohang-si (KR); DAESU LEE, Pohang-si (KR); SANGHYEON KIM, Pohang-si (KR); Gi-jeong HAN, Pohang-si (KR)

(21) Appl. No.: 18/954,931

(22) Filed: Nov. 21, 2024

(30) Foreign Application Priority Data
Jan. 19, 2024 (KR) 10-2024-009085

(51) Int. Cl. H01L 29/24; C30B 29/22; H01L 29/861

(52) U.S. Cl. CPC H10D 62/80; C30B 29/22; H10D 8/422

(57) ABSTRACT

A diode device and a semiconductor device including the diode device, the diode device including an active layer including a 5d transition mixed-metal oxide including a first element and a second element different from the first element. The composition ratios of the first element relative to the second element incrementally varies along a thickness direction of the active layer.

### CROSS-REFERENCE TO RELATED APPLICATION

This application claims priority to Korean Patent Application No. 10-2024-0009085 filed in the Korean Intellectual Property Office on Jan. 19, 2024, and all the benefits accruing therefrom under 35 U.S.C. § 119, the entire contents of which are herein incorporated by reference.

### BACKGROUND

### 1. Field

Diode devices and semiconductor devices are disclosed.

### 2. Description of the Related Art

Diode devices may include a pn-junction if a p-type semiconductor is combined with a n-type semiconductor to form a potential barrier voltage across the diode junction. The device may be used to control the movement of charge carriers generated by an electric field, e.g., holes and electrons, at the junction of the p-type semiconductor and the n-type semiconductor. Accordingly, current may flow if an applied voltage is greater than a strength of the electric field, and current may be impeded if an applied voltage less than the strength of the electric field.

### SUMMARY

An embodiment provides a diode device or a semiconductor device with improved performance.

Another embodiment provides a semiconductor device including the diode device.

Another embodiment provides a method of making the diode device.

According to an embodiment, a diode device includes an active layer including a 5d transition mixed-metal oxide including a first element and a second element different from the first element, wherein a composition ratio of the first element relative to the second element may incrementally vary along the thickness direction of the active layer. The active layer may include a plurality of atomic layers with different composition ratios of the first element relative to the second element. For example, along a thickness direction of the active layer, a mole fraction of the first element to the first element and the second element may decrease, or a mole fraction of the second element to the first element and the second element may increase.

The 5d transition mixed-metal oxide may be represented by Chemical Formula 1.

XₐZ₍₁₋ₐ₎AO₃ Chemical Formula 1

In Chemical Formula 1,
X is the first element,
Z is the second element,
Z may be the second element,
A may be a 5d transition metal, and
indice a may incrementally vary from 0 to 1 along a thickness direction of the active layer.

The active layer may include a first region, a second region, and a third region sequentially arranged along the thickness direction of the active layer, and the second region may include a plurality of atomic layers in which indice a of Chemical Formula 1 incrementally decreases from the first region to the third region.

The second region of the active layer may include first, second, third, and fourth active layer sub-regions sequentially arranged along the thickness direction of the active layer, and a mole fraction of the first element to the first element and the second element may decrease, and a mole fraction of the second element to the first element and the second element may increase, in the first, second, third, and fourth active layer sub-regions along the thickness direction.

The mole fractions of the first element in the first sub-region, the second sub-region, the third sub-region, and the fourth sub-region may be represented as follows; 0.7<a<1.0, 0.5<a≤0.7, 0.3<a≤0.5, and 0<a≤0.3, respectively.

The first region of the active layer may have a=1, and the third region of the active layer may have a=0.

The 5d transition mixed-metal oxide may be perovskite iridate.

The first element and the second element may each be selected from Group 2 (alkaline earth) elements.

The 5d transition mixed-metal oxide may be represented by SrₐCa₍₁₋ₐ₎IrO₃, where indice a may incrementally vary from 0 to 1 along the thickness direction of the active layer.

The active layer may not include a counterpart material for pn junction.

The active layer may be an epitaxially grown thin film.

According to another embodiment, a diode device includes a substrate, and an active layer on the substrate, wherein the active layer includes a plurality of atomic layers including a 5d transition metal oxide represented by SrₐCa₍₁₋ₐ₎IrO₃ (0≤a≤1), and a composition ratio of Sr and Ca varies along a thickness direction of the active layer.

The indice a may incrementally vary from 0 to 1 along the thickness direction of the active layer.

The active layer may include a first region, second region, and third region as noted above. The second region of the active layer may include a first, second, third, and fourth, active layer sub-regions sequentially arranged along a thickness direction of the active layer, wherein a mole fraction of strontium (Sr) in the first, second, third, and fourth, active layer sub-regions may be 0.7<a<1.0, 0.5<a≤0.7, 0.3<a≤0.5, and 0<a≤0.3, respectively.

The active layer may not include a counterpart material for pn junction.

The first, second, third, and fourth, active layer sub-regions may each include one or more atomic layers, e.g., 1 to 6 atomic layers or 1 to 3 atomic layers, each of which may be an epitaxially grown thin film.

According to another embodiment, a semiconductor device including the diode device is provided.

The manufacturing process of diode devices may be simplified and performance improved.

### BRIEF DESCRIPTION OF THE DRAWINGS

FIG. 1 is a cross-sectional view showing an example of a diode device according to an embodiment,

FIG. 2 is a schematic view showing a substrate and a plurality of atomic layers of the diode device of FIG. 1,

FIG. 3 is a graph showing the oscillation and pattern of a high-speed reflection electron diffraction device (RHEED) that confirms the stacking of one layer while controlling the element composition ratio of each layer of the SrₐCa₍₁₋ₐ₎IrO₃ film when manufacturing a diode device according to an embodiment,

FIG. 4 is an enlarged image of part A of FIG. 3,

FIG. 5 is a plot showing magnetic field sweep measurement results when the magnetic field direction, internal electric field direction, and current direction are perpendicular (⊖ is) 0° to the device according to Example, and when the magnetic field direction and current direction are parallel (⊖ is) 90° to the device according to Example, and

FIG. 6 is a plot showing magnetic field sweep measurement results when the magnetic field direction, internal electric field direction, and current direction are perpendicular to the device according to Comparative Example, and when the magnetic field direction and current direction are parallel to the device according to Comparative Example.

### DETAILED DESCRIPTION

Hereinafter, the embodiments will be described in detail so that those of ordinary skill in the art may easily implement them. However, the actually applied structure may be implemented in several different forms and is not limited to the embodiments described herein. The terminology used herein is for the purpose of describing example implementations only and is not intended to limit the invention.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

Herein, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

The drawings and description are to be regarded as illustrative in nature and not restrictive. In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer” includes a construction having a shape formed on a part of a region, in addition to a construction having a shape formed on an entire region.

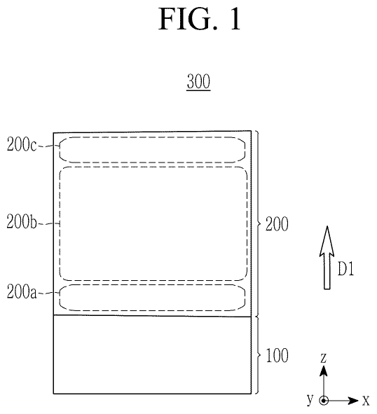

The term “along the thickness direction of the active layer” refers to direction D1 as indicated in FIG. 1, that is, in a direction from first region 200a to second region 200b, and then to third region 200c.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±5%, of the indicated value or within a standard deviation.

Hereinafter, “metal” is interpreted as a concept including metals and metalloids (semi-metals).

Hereinafter, an example of a diode device according to an embodiment will be described with reference to the drawings.

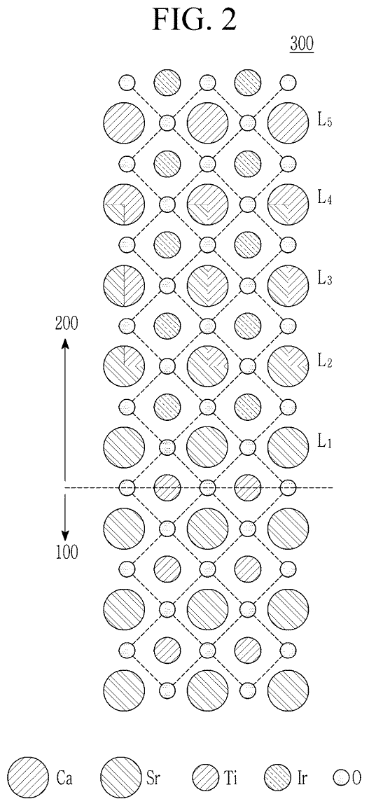

FIG. 1 is a cross-sectional view showing an example of a diode device according to an embodiment and FIG. 2 is a schematic view showing a plurality of atomic layers according to an embodiment of the diode device of FIG. 1.

Referring to FIG. 1, a diode device 300 according to an embodiment includes a substrate 100 and an active layer 200.

The substrate 100 may be a crystalline substrate, for example, a single crystal substrate or a polycrystalline substrate.

The single crystal substrate may have a structure in which the entire crystal is composed of single crystals regularly arranged along a certain crystal axis and may have substantially no grain boundaries. The single crystal substrate may have, for example, a cubic, trigonal, orthorhombic, hexagonal, or rhombohedral crystal structure. The crystal direction (the plane direction) of the single crystal substrate may be, for example, (100), (111), (110), or (010).

The single crystal substrate may include, for example, a metal single crystal, a semi-metal single crystal, a binary compound, an oxide, a nitride, a sulfide, a phosphide, an arsenide, a carbide, or a combination thereof, but is not limited thereto. As an example, the single crystal substrate may be an oxide, and may include, for example, at least one of barium (Ba) or strontium (Sr) and titanium (Ti), for example, SrTiO₃ or M-doped SrTiO₃ (wherein M may be one or more elements selected from a metal or a semi-metal, for example, Nb), BaTiO₃ or M-doped BaTiO₃ (wherein M may be one or more elements selected from a metal or a semi-metal, for example, Nb).

The active layer 200 may be disposed on the substrate 100 and may be an epitaxially grown thin film on the substrate 100. The active layer 200 may include a topological material, and the topological material may be a metallic material, also called a topological metal. The topological material may further include at least one metal element and optionally a semi-metal element and/or a non-metallic element, and may be a single crystal or polycrystalline compound with a predetermined crystal structure.

As an example, the active layer 200 may include a 5d transition mixed-metal oxide including a first element and a second element different from the first element. The 5d transition mixed-metal oxide may be, for example, a 5d perovskite material. The first element and the second element may be elements belonging to Group 2 (alkaline-earth), for example, and may be selected from strontium (Sr), calcium (Ca), barium (Ba), or magnesium (Mg). For example, a first element or the second element may be Sr, and the other of the first element and the second element may be Ca. For example, the first element may be Sr and the second element may be Ca, or the first element may be Ca and the second element may be Sr. For example, the 5d transition mixed-metal oxide may be a perovskite iridate.

In accordance with an embodiment, a composition ratio of the first element relative to the second element in the 5d transition mixed-metal oxide may incrementally vary along the thickness direction (e.g., z direction) of the active layer 200. For example, a composition ratio of the first element relative to the second element may incrementally vary along one direction (e.g., the first direction D1). Herein, the composition ratios may be an elemental mole fraction of the first element or mole fraction of the second element relative to the first element and the second element (for example, the total number of moles of the first element and the second element).

In accordance with an embodiment, the active layer 200 may include a plurality of atomic layers with different composition ratios of the first element relative to the second element along the thickness direction (e.g., z direction) beginning from the surface of the substrate 100, and the composition ratios of the first element relative to the second element may be controlled for each atomic layer. For example, a composition ratio of the first element relative to the second element in one of the plurality of atomic layers may be different from a composition ratio of the first element relative to the second element in the adjacent atomic layer. For example, in a plurality of atomic layers stacked along the thickness direction (e.g., z direction) from the surface of the substrate 100, the mole fraction of the first element relative to the second element may decrease along the first direction D1 and the mole fraction of the second element to the first element and the second element may increase.

In this way, the active layer 200 includes a plurality of atomic layers with different composition ratios of the first element relative to the second element along the thickness direction, thereby breaking an inversion symmetry at the interface of adjacent atomic layers due to the Rashba effect, and thus, realizing high non-mutual conduction phenomenon when an external magnetic field is applied. Herein, the non-mutual conduction phenomenon is a phenomenon in which the resistance of a material changes depending on the direction of the current flowing through the material. In other words, the resistance at positive current and the resistance at negative current have different properties, which may be a characteristic of the diode device. Accordingly, the active layer 200 may implement diode characteristics using only the aforementioned metallic material without a separate counterpart material for forming a pn junction.

For example, a difference in resistance between positive and negative currents may be confirmed by measuring a voltage difference corresponding to 2ω, which is twice the frequency, when an alternating current with a frequency of ω flows through the active layer 200. By confirming the tendency for this signal to become larger depending on the size of the magnetic field or the strength of the current, and confirming the angular dependence depending on the direction of the magnetic field, an electric field is formed due to the breaking of inversion symmetry inside the active layer 200.

As an example, the active layer 200 may include 5d transition mixed-metal oxide represented by Chemical Formula 1.

XₐZ₍₁₋ₐ₎AO₃ Chemical Formula 1

In Chemical Formula 1,
X may be a first element,
Z may be a second element,
A may be a 5d transition metal, and
indice a may incrementally vary from 0 to 1 along a thickness direction of the active layer.

The active layer 200 may include a first region 200a, a second region 200b, and a third region 200c sequentially arranged along the thickness direction (e.g., z direction) from the surface of the substrate 100. The first region 200a of the active layer 200 may be in contact with the surface of the substrate 100, the third region 200c may be a region furthest from the substrate 100, and the second region 200b may be disposed between the first region 200a and the third region 200c. The second region 200b may be thicker than the first region 200a or third region 200c.

As an example, the active layer 200 may include a plurality of atomic layers stacked along the thickness direction (e.g., z direction) from the surface of the substrate 100. Along the first direction D1, a mole fraction of the first element to the first element and the second element may decrease and a fraction of the second element to the first element and the second element may increase.

Accordingly, the first region 200a of the active layer 200 in contact with the surface of the substrate 100 may have a maximum mole fraction of the first element to the first element and the second element. For example, the first region 200a of the active layer 200 may include a 5d transition mixed-metal oxide represented by XAO₃ with a=1 in Chemical Formula 1.

The composition ratio of the first element relative to the second element in the second region 200b of the active layer 200 may incrementally vary along the thickness direction (i.e., the first direction D1), and may include a plurality of atomic layers in which indice a in Chemical Formula 1 incrementally changes in a range of less than 1 to about 0.

For example, the second region 200b of the active layer 200 may include first, second, and third, atomic layer sub-regions arranged along the thickness direction D1. In the first, second, and third atomic layer sub-regions, a mole fraction of the first element to the first element and the second element may decrease, and a mole fraction of the second element to the first element and the second element may increase, along the thickness direction. For example, in the second region 200b of the active layer 200, the mole fraction of the first element in the first atomic layer sub-region, the second atomic layer sub-region, and the third atomic layer sub-region, may incrementally decrease along the thickness direction, and may be 0.7<a<1.0, 0.3<a≤0.7 and 0<a≤0.3, respectively. Accordingly, the mole fraction of the second element in the first atomic layer sub-region, second atomic layer sub-region, and third atomic layer sub-region, in accordance with Chemical Formula 1 may incrementally increase. For example, indice a may each be 0.75, 0.50, and 0.25, in the first atomic layer sub-region, the second atomic layer sub-region, and the third atomic layer sub-region, of the second region 200b, respectively.

In accordance with an embodiment, the second region 200b of the active layer 200 may include first, second, third, and fourth, atomic layer sub-regions arranged along the thickness direction. In the first, second, third and fourth, atomic layer sub-regions, the mole fraction of the first element to the first element and the second element may decrease, and the mole fraction of the second element to the first element and the second element may increase. For example, in the second region 200b of the active layer 200, the fraction of the first element in the first atomic layer sub-region, the second atomic layer sub-region, the third atomic layer sub-region, and the fourth atomic layer sub-region, may incrementally decrease, and each may be 0.7<a<1.0, 0.5<a≤0.7, 0.3<a≤0.5, and 0<a≤0.3, respectively, Accordingly, the mole fraction of the second element in the first atomic layer sub-region, the second atomic layer sub-region, the third atomic layer sub-region, and the fourth atomic layer sub-region, in accordance with Chemical Formula 1 may incrementally increase. For example, indice a may each be 0.80, 0.60, 0.40, and 0.20, respectively.

The third region 200c of the active layer 200 may have a minimum mole fraction of the first element to the first element and the second element, and may include, for example, a 5d transition mixed-metal oxide represented by ZAO₃ with a=0 in Chemical Formula 1.

For example, when the first element is Sr and the second element is Ca, the 5d transition mixed-metal oxide may be represented by SrₐCa₍₁₋ₐ₎IrO₃. The first region 200a of the active layer 200 may include a 5d transition mixed-metal oxide represented by SrIrO₃, the second region 200b of the active layer 200 may include a 5d transition mixed-metal oxide represented by SrₐCa₍₁₋ₐ₎IrO₃ (0<a<1) and in which the mole fractions of Sr and Ca incrementally vary in a thickness direction. The third region 200c of the active layer 200 may include a 5d transition mixed-metal oxide represented by CaIrO₃.

Referring to FIG. 2, the diode device 300 according to an embodiment includes a substrate 100 having a SrTiO₃ single crystal structure and an active layer 200 including a metallic material, i.e., the 5d transition mixed-metal oxide represented by SrₐCa₍₁₋ₐ₎IrO₃. The active layer 200 includes an atomic layer L₁ in the first region 200a, a plurality of atomic layers, e.g., L₂ to L₄. in the second region 200b, and an atomic layer L₅ in the third region 200c. The atomic layer L₁ in the first region 200a may include a metallic material 5d transition mixed-metal oxide represented by SrIrO₃, the plurality of atomic layers L₂ to L₄ in the second region 200b may include a metallic material 5d transition mixed-metal oxide where a composition ratio of Sr relative to Ca incrementally varies along the thickness direction, and the atomic layer L₅ in the third region 200c may include a metallic material 5d transition mixed metal oxide represented by CaIrO₃.

In the atomic layers L₂ to L₄ of the second region 200b, the mole fraction of Sr to Sr and Ca may decrease along the thickness direction and the mole fraction of Ca may increase along the thickness direction. For example, the mole fraction of Sr in atomic layer L₂, atomic layer L₃, and atomic layer L₄ may be 0.7<a<1.0, 0.3<a≤0.7, and 0<a≤0.3, respectively. As an example, indice a may be 0.75, 0.50, and 0.25, respectively. As another embodiment, the second region 200b may include four atomic layers in which a composition ratio of Sr and Ca incrementally varies. In this case, the mole fractions of Sr in the second region 200b, of the four atomic layers, which are formed sequentially, may be 0.7<a<1.0, 0.5<a≤0.7, 0.3<a≤0.5, and 0<a≤0.3, respectively. For example, indice a may be 0.80, 0.60, 0.40, and 0.20, respectively. However, the present disclosure is not limited thereto, and the second region 200b may include five or more atomic layers. In this case, the mole fraction of Sr of the plurality of atomic layers may incrementally decrease and the mole fraction of Ca may gradually, i.e., incrementally increase.

The active layer 200 may include 5d transition mixed-metal oxide, which is a metallic material, as an active material, and as described above, includes a plurality of atomic layers having different composition ratios of the first element relative to the second element along the thickness direction. The difference in the composition ratios disrupts or breaks an inversion symmetry at the interface of adjacent atomic layers, and thus, the active layer 200 exhibits a high non-mutual conduction phenomenon when an external magnetic field is applied to realize characteristics necessary for a diode device. Accordingly, the active layer 200 may be made of a metallic material such as the aforementioned 5d transition mixed-metal oxide. Accordingly, the active layer 200 may not include a separate counterpart material for forming a pn junction, other than the 5d transition mixed-metal oxide.

In this way, the diode device 300 according to an embodiment includes a plurality of atomic layers including metallic materials with different composition ratios of the first element relative to the second element along a thickness direction, thereby breaking an inversion symmetry at the interface of adjacent atomic layers due to the Rashba effect. The break in the inversion symmetry provides a high non-mutual conduction phenomenon when an external magnetic field is applied, and accordingly, the material realizes diode characteristics with only the aforementioned single metallic material without a separate counterpart material to form a pn junction.

Accordingly, in order to implement the diode device 300, without depositing p-type semiconductors and n-type semiconductors with different electrical and thermal properties and adding a separate ion implantation process, the active layer 200 may be formed by epitaxially growing the aforementioned single metallic material and the manufacturing process may be simplified.

In addition, in a diode device using a more traditional pn junction, the size of the electric field that may be generated by electrons and holes is limited, and thus, the size of the voltage that may be rectified is limited. In contrast, the diode device 300 according to the aforementioned embodiment may greatly adjust the resistance difference depending on the size of the current flowing through the material (single metallic material), and thus, the device 300 may be effectively applied as a high-voltage diode device. For example, in the active layer 200 including a plurality of atomic layers including metallic materials with different composition ratios of the first element relative to the second element, a size of the internal electric field changes depending on the difference in the composition ratio of the first element relative to the second element between adjacent atomic layers. Accordingly, a size of the rectification action may be adjusted by changing the size of the internal electric field by adjusting the composition ratios of the first element and the second element during the epitaxial growth process.

In addition, as described above, by using a single metallic material as the active material of the active layer 200, heat loss may be lower than that of a semiconductor material, resulting in improved efficiency, and by using a 5d transition mixed-metal oxide as a single metallic material, the oxidation resistance of the diode device 300 may be improved.

The aforementioned diode device 300 may be applied to various semiconductor devices, for example, a LOGIC device or a memory device.

The aforementioned diode device 300 or semiconductor device using the same may be included in various electronic devices, and the electronic device may include, for example, mobile devices, computers, laptops, tablet PC, smart watches, sensors, digital cameras, electronic books, network devices, car navigators, Internet of Things (IoT), Internet of Everything (IoE), drones, door locks, safes, automated teller machines (ATMs), security devices, medical devices, automobile electrical components, or etc., but are not limited thereto.

Hereinafter, the embodiments are illustrated in more detail with reference to examples. However, the following examples are for illustrative purposes only and do not limit the scope of rights.

### MANUFACTURING OF DEVICES—EXAMPLES

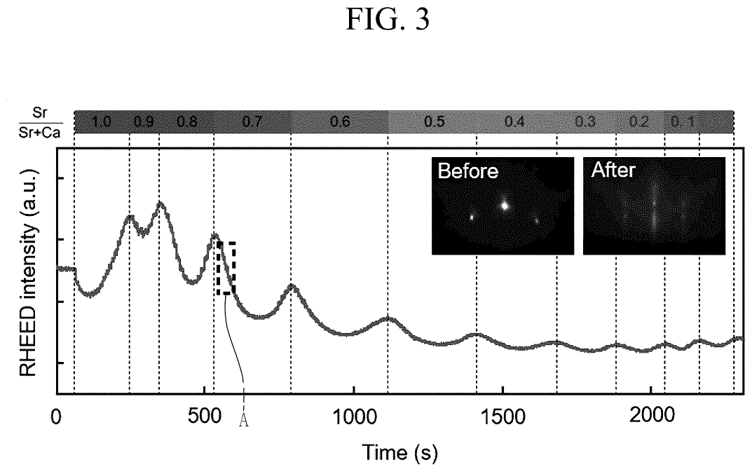

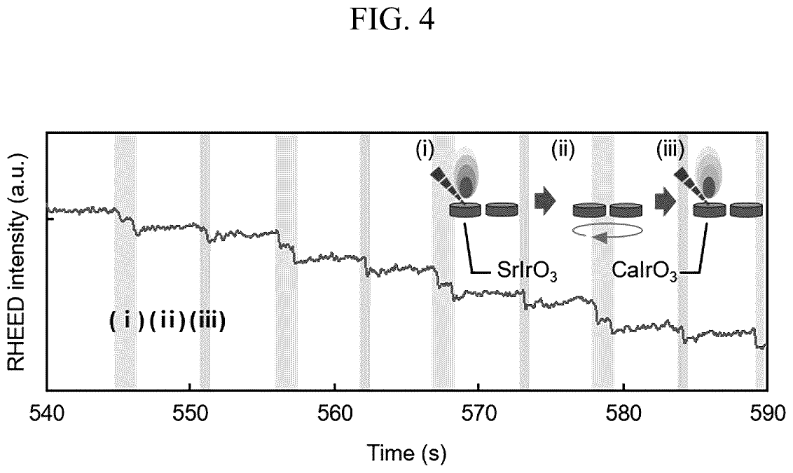

A SrₐCa₍₁₋ₐ₎IrO₃ film (thickness: 4.3 nm) is epitaxially grown on a SrTiO₃ (001) substrate by pulsed laser deposition (PLD) using a SrIrO₃ target and a CaIrO₃ target. The SrₐCa₍₁₋ₐ₎IrO₃ film includes a plurality of atomic layers (e.g., SrIrO₃, Sr_{0.8}Ca_{0.2}IrO₃, Sr_{0.4}Ca_{0.6}IrO₃, Sr_{0.2}Ca_{0.8}IrO₃, and CaIrO₃) with atomic layers having a different composition ratio of Sr and Ca. As indicated, the above film has a graduated composition change in both Sr and Ca, e.g., with respect to Sr from 1 (SrTiO₃) to 0 (CaIrO₃) and likewise with respect to Ca from 0 (SrTiO₃) to 1 (CaIrO₃). The composition ratio with respect to Sr and Ca for each atomic layer can be confirmed in real time using a reflection high energy electron diffraction (RHEED) device (see FIGS. 3 and 4).

FIG. 3 shows the oscillation and pattern of a reflection high energy electron diffraction (RHEED) device that confirms the stacking of one layer while controlling the element composition ratio of each layer of the SrₐCa₍₁₋ₐ₎IrO₃ film when manufacturing a diode device according to an embodiment. FIG. 4 is an enlarged image of part A of FIG. 3. Moreover, because the composition ratio in real time can be confirmed from the plotted data of FIG. 3, it is possible to form a plurality of atomic layers with the adjusted composition ratios of Sr and Ca.

Thereafter, a PMMA c4 resist is spin-coated on the SrₐCa₍₁₋ₐ₎IrO₃ film and baked at 120° C. for 2 minutes to form an insulating layer A conductive layer is then formed on the PMMA layer by spin coating a PEDOT conductive polymer solution (PEDOT:Triton X100=weight ratio of 99:1). The marker is lithographed using SEM equipment, immersed in a developer at 18° C. (DI water:IPA=volume ratio of 1:1), and developed for 30 seconds to form Cr (5 nm) and Au (40 nm) markers.

A second PMMA c4 resist layer is spin-coated on the markers and baked at 120° C. for 2 minutes to form a second insulating layer followed by a second PEDOT conductive polymer solution (PEDOT:Triton X100=weight ratio of 99:1) that is spin-coated. Lithography is then conducted on the device structure followed by immersion in a developer (DI water:IPA=volume ratio of 1:1) at 18° C. for 30 seconds to form an electrode with dimensions of 10 micrometer (μm)×60 μm. In a manufactured device.

### Comparative Example

A device is manufactured in the same manner as in the Example above, except that a Sr_{0.5}Ca_{0.5}IrO₃ film with a constant composition ratio throughout the film is formed instead of the graduated SrₐCa₍₁₋ₐ₎IrO₃ film that includes a plurality of atomic layers (e.g., SrIrO₃, Sr_{0.8}Ca_{0.2}IrO₃, Sr_{0.4}Ca_{0.6}IrO₃, Sr_{0.2}Ca_{0.8}IrO₃, and CaIrO₃) with different composition ratios of Sr and Ca.

### Evaluation

An alternating current is flowed through the source and drain terminals of the electrodes of the devices according to the Example and Comparative Example, and the voltage between the measurement terminals is measured. When measuring a voltage, one measures a signal that is twice the frequency of the alternating current, and the magnetic field is measured by sweeping the magnetic field from −10 to 10T depending on the strength of the applied current.

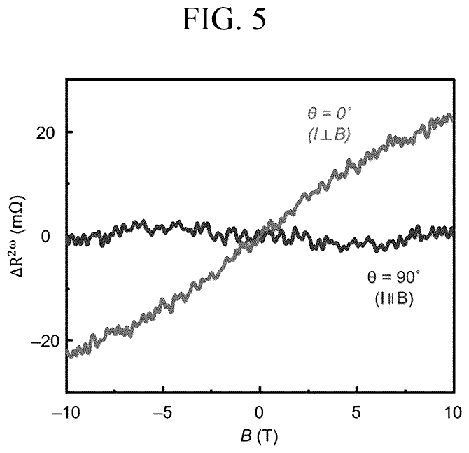

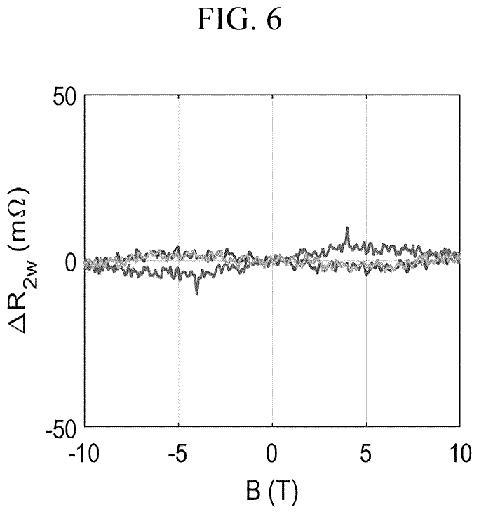

FIG. 5 is a plot showing magnetic field sweep measurement results when the magnetic field direction, internal electric field direction, and current direction are all perpendicular to the device according to Example (⊖ is) 0°, and when the magnetic field direction and current direction are parallel to the device according to Example (⊖ is 90°). FIG. 6 is a plot showing magnetic field sweep measurement results when the magnetic field direction, internal electric field direction, and current direction are all perpendicular to the device according to the Comparative Example, and when the magnetic field direction and current direction are parallel to the device according to the Comparative Example.

Referring to FIG. 5, for the device according to the Example, current flows when the magnetic field direction, internal electric field direction, and current direction are all perpendicular and current does not flow when the magnetic field direction and the current direction are parallel. Accordingly, we confirm that the device according to the Example applies a rectification action that allows current to flow only when desired, and therefore may be applicable as a diode device.

In contrast, referring to FIG. 6, in the device according to the Comparative Example, no current flows when the magnetic field direction, internal electric field direction, and current direction are all perpendicular. Moreover, no current flows when the when the magnetic field direction and current direction are parallel. Accordingly, we confirm that the device according to Comparative Example is not applicable as a diode device. While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A diode device comprising:
an active layer comprising a 5d transition mixed-metal oxide, the 5d transition mixed-metal oxide including a first element and a second element different from the first element,
wherein a composition ratio of the first element relative to the second element varies along a thickness direction of the active layer.

2. The diode device of claim 1, wherein the active layer comprises a plurality of atomic layers, wherein the plurality of atomic layers have a different composition ratio of the first element relative to the second element.

3. The diode device of claim 2, wherein along the thickness direction of the active layer, a mole fraction of the first element to the first element and the second element decreases, or a mole fraction of the second element to the first element and the second element increases.

4. The diode device of claim 1, wherein the 5d transition mixed-metal oxide is represented by Chemical Formula 1:
XₐZ₍₁₋ₐ₎AO₃ Chemical Formula 1
wherein, in Chemical Formula 1,
X is the first element,
Z is the second element,
A is a 5d transition metal, and
indice a incrementally varies from 0 to about 1 along the thickness direction of the active layer.

5. The diode device of claim 4, wherein
the active layer comprises a first region, a second region, and a third region sequentially arranged along the thickness direction of the active layer,
wherein the indice a is about 0 in the first region,
the second region comprises a plurality of atomic layers in which the indice a of Chemical Formula 1 incrementally decreases from the first region to the third region.

6. The diode device of claim 5, wherein
the second region of the active layer comprises first, second, third, and fourth, active layer sub-regions sequentially arranged along the thickness direction of the active layer, and
a mole fraction of the first element to the first element and the second element decreases, and a mole fraction of the second element to the first element and the second element increases, in the first, second, third, and fourth active layer sub-regions along the thickness direction.

7. The diode device of claim 6, wherein the mole fractions of the first element in the first sub-region, the second sub-region, the third sub-region, and the fourth sub-region are: 0.7<a<1.0; 0.5<a≤0.7; 0.3<a≤0.5; and 0<a≤0.3; respectively.

8. The diode device of claim 5, wherein
the first region of the active layer a is 1, and
the third region of the active layer a is 0.

9. The diode device of claim 1, wherein the 5d transition mixed-metal oxide is perovskite iridate.

10. The diode device of claim 1, wherein the first element and the second element are Group 2 elements.

11. The diode device of claim 1, wherein the 5d transition metal oxide is represented by SrₐCa₍₁₋ₐ₎IrO₃.

12. The diode device of claim 1, wherein the active layer does not comprise a counterpart material for pn junction.

13. The diode device of claim 1, wherein the active layer is an epitaxially grown thin film.

14. A diode device comprising:
a substrate, and
an active layer on the substrate,
wherein the active layer comprises a plurality of atomic layers comprising a 5d transition mixed-metal oxide represented by SrₐCa₍₁₋ₐ₎IrO₃, wherein 0≤a≤1, and
a composition ratio of Sr relative to Ca varies along a thickness direction of the active layer.

15. The diode device of claim 14, wherein the indice a incrementally decreases from 0 to 1 along the thickness direction of the active layer.

16. The diode device of claim 14, wherein
the active layer comprises a first region, a second region, and a third region, sequentially arranged along the thickness direction of the active layer,
wherein the second region of the active layer comprises a first, second, third, and fourth, active layer sub-regions sequentially arranged along the thickness direction of the active layer, and
a mole fraction of Sr in the first, second, third, and fourth, active layer sub-regions is 0.7<a<1.0, 0.5<a≤0.7, 0.3<a≤0.5, and 0<a≤0.3, respectively.

17. The diode device of claim 14, wherein the active layer does not comprise a counterpart material for pn junction.

18. The diode device of claim 14, wherein the first, second, third, and fourth active layer sub-regions comprise one or more atomic layers each of which is an epitaxially grown thin film.

19. A semiconductor device comprising the diode device of claim 1.

20. A semiconductor device comprising the diode device of claim 14.
